(19) United States
(12) Patent Application Publication
(10) Pub. No.: US 2025/0294710 A1
(43) Pub. Date: Sep. 18, 2025

(54) ENHANCED VAPOR CHAMBER HEATSINK

(71) Applicant: Cisco Technology, Inc., San Jose, CA (US)

(72) Inventors: Phong H. HO, Cary, NC (US); Stephen A. SCEARCE, Apex, NC (US); Craig D. DUBRULE, Cary, NC (US); Hang T. TRAN, San Jose, CA (US)

(21) Appl. No.: 18/607,163

(22) Filed: Mar. 15, 2024

(51) Int. Cl. H05K 7/20

(52) U.S. Cl. CPC H05K 7/20418; H05K 7/20336; H05K 7/20436

(57) ABSTRACT

An enhanced vapor chamber heat sink is provided. In one aspect, a heat sink includes a vapor chamber that includes a bottom portion, a top portion spaced from the bottom portion, and a curved connector connecting the bottom portion and the top portion. The bottom portion, the curved connector, and the top portion define a chamber in which a working fluid is received. The heat sink also includes a plurality of fins extending between the bottom portion and the top portion. Further, the heat sink includes a thermal interface material (TIM) layer disposed on the top portion, the curved connector, or both. The heat sink also includes a conducting cover contacting the TIM layer.

### TECHNICAL FIELD

Embodiments presented in this disclosure generally relate to heat sinks, and more particularly, to vapor chamber heat sinks.

### BACKGROUND

Cooling high power devices using air in high density applications can present certain challenges. For instance, cooling Central Processing Units (CPUs) in high density applications, such as network security devices, can be challenging given the high power dissipation of the CPUs, relatively low maximum case temperatures, and mass requirements for a cooling heat sink. Vapor chambers are often used for such cooling heat sinks but the fins thereof typically become cooler with increasing height as they extend away from the vapor chamber, leading to cooling inefficiencies. It has also been challenging to efficiently transfer heat from the fins to an external body.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate typical embodiments and are therefore not to be considered limiting; other equally effective embodiments are contemplated.

FIG. 1 is a perspective view of a heat sink having a vapor chamber according to an example embodiment of the present disclosure.

FIG. 2 is a side view of the heat sink of FIG. 1.

FIG. 3 is a perspective view of a heat sink having a vapor chamber according to another example embodiment of the present disclosure.

FIG. 4 is a perspective view of a heat sink having a vapor chamber according to yet another example embodiment of the present disclosure.

FIG. 5 is a perspective view of a heat sink having a vapor chamber according to a further example embodiment of the present disclosure.

FIG. 6 is a flow diagram for a method of cooling a heat source of an apparatus according to an example embodiment of the present disclosure.

To facilitate understanding, identical reference numerals have been used, where possible, to designate identical elements that are common to the figures. It is contemplated that elements disclosed in one embodiment may be beneficially used in other embodiments without specific recitation.

### DESCRIPTION OF EXAMPLE EMBODIMENTS

### Overview

One embodiment presented in this disclosure is a heat sink. The heat sink includes a vapor chamber. The vapor chamber includes a bottom portion; a top portion spaced from the bottom portion; and a curved connector connecting the bottom portion and the top portion, wherein the bottom portion, the curved connector, and the top portion define a chamber in which a working fluid is received. The heat sink also includes a plurality of fins extending between the bottom portion and the top portion. The heat sink also includes a thermal interface material (TIM) layer disposed on the top portion, the curved connector, or both. Further, the heat sink includes a conducting cover contacting the TIM layer.

Another embodiment presented in this disclosure is an apparatus. The apparatus includes an integrated circuit and a heat sink arranged relative to the integrated circuit for providing cooling thereto. The heat sink includes a vapor chamber having a bottom portion, a top portion spaced from the bottom portion, and a curved connector connecting the bottom portion and the top portion, wherein the bottom portion, the curved connector, and the top portion define a chamber in which a working fluid is received. The heat sink also includes a plurality of fins extending between the bottom portion and the top portion. Further, the heat sink includes a thermal interface material (TIM) layer disposed on the top portion, the curved connector, or both. The heat sink also includes a conducting cover contacting the TIM layer.

Yet another embodiment presented in this disclosure is a method. The method includes providing an apparatus having an integrated circuit (IC) and a heat sink arranged relative to the IC for providing cooling thereto. The heat sink includes a vapor chamber having a bottom portion, a top portion spaced from the bottom portion, and a curved connector connecting the bottom portion and the top portion, wherein the bottom portion, the curved connector, and the top portion define a chamber in which a working fluid is received. The heat sink also includes a plurality of fins extending between the bottom portion and the top portion. Further, the heat sink includes a thermal interface material (TIM) layer disposed on at least one surface of the vapor chamber. The heat sink also includes a conducting cover contacting the TIM layer. The method further includes cooling the IC during operation of the apparatus using the heat sink. In some implementations, in cooling the IC during operation of the apparatus, heat is transferred to the plurality of fins at their respective top ends by the top portion and at their respective bottom ends by the bottom portion or a base of the heat sink that is in thermal communication with the bottom portion. Further, in such implementations, in cooling the IC during operation of the apparatus, the bottom portion and the top portion operate substantially isothermally in such a way so as to provide an additional heat path for heat to be transferred from the top portion to the conducting cover by way of the TIM layer and from the conducting cover to one or more additional heat sinks.

A further embodiment presented in this disclosure is a vapor chamber. The vapor chamber includes a bottom portion, a top portion spaced from the bottom portion by a plurality of fins, and a curved connector connecting the bottom portion and the top portion, wherein the bottom portion, the curved connector, and the top portion define a chamber in which a working fluid is received.

### EXAMPLE EMBODIMENTS

Disclosed herein are various embodiments of improved vapor chamber heat sinks. In one example aspect, a heat sink is provided to cool a device, such as an integrated circuit of an apparatus. The heat sink includes an enhanced vapor chamber that has a bottom portion, a top portion, and a curved connector that connects the bottom portion and top portion, which can be arranged parallel to one another. The top portion is spaced from the bottom portion, e.g., vertically spaced. Fins extend between and connect the bottom portion and the top portion. In this regard, the bottom portion contacts the respective bottoms of the fins and the top portion contacts the respective tops of the fins. The heat sink can also include a Thermal Interface Layer (TIM) disposed on a surface of the vapor chamber, such as a top planar surface of the top portion and/or an external surface of the curved connector. The heat sink can also include a conducting cover disposed on the TIM layer.

A heat sink having such an architectural arrangement can provide certain advantages, benefits, and/or technical effects. For instance, such a heat sink can achieve: (1) improved fin efficiency by allowing the top of the fins to work as efficiently as the bottom of the fins, at least due to the fins being contacted at their respective tops and bottoms by the top portion and bottom portion; and (2) the TIM layer can conduct heat away from the top portion to the conducting cover, which provides an additional heat path for heat to be transferred away from the device to be cooled. The conducting cover can be thermally coupled with one or more additional heat removal devices or heat sinks. Accordingly, heat can be transferred away from the device to be cooled using this additional heat path. Notably, the architecture of the enhanced vapor chamber allows the bottom portion and the top portion to operate substantially isothermally, or stated differently, at substantially near the same temperature. As a result, the additional heat path is an efficient conductive heat path even though the top portion is vertically offset from the device to be cooled. The combined effect of these advantages, benefits, and/or technical effects can provide a high efficiency and compact heat sink. Such a heat sink can be used to cool high power devices using air in high density applications, such as cooling an IC in a network device.

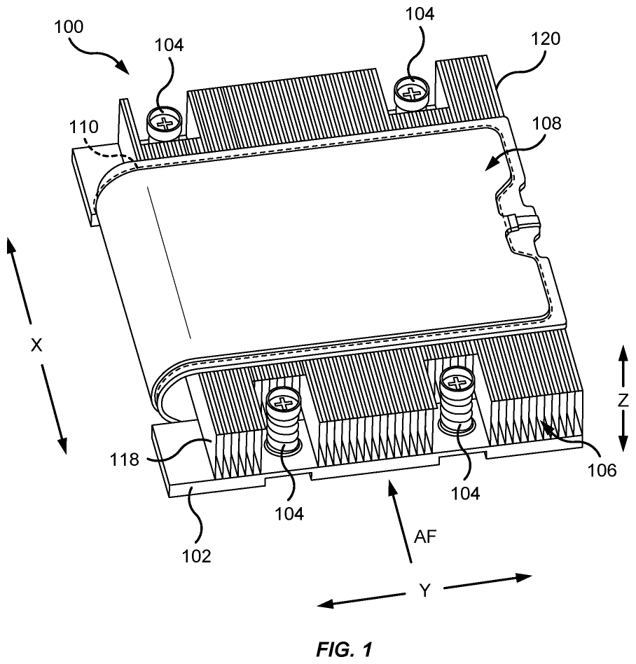

FIG. 1 is a perspective view of a heat sink 100 according to an example embodiment of the present disclosure. The heat sink 100 can be implemented in many different types of apparatuses to provide cooling to one or more powered devices thereof. For instance, the heat sink 100 can be incorporated into a network device (e.g., a firewall) to cool an Integrated Circuit (IC), such as a Central Processing Unit (CPU). In some embodiments, multiple heat sinks having a same or similar architecture as the heat sink 100 of FIG. 1 can be implemented into a single apparatus, such one heat sink for each CPU of a network device. Moreover, for reference, the heat sink 100 defines a first direction X, a second direction Y, and a third direction Z, which are mutually perpendicular to one another to define an orthogonal direction system. The first direction X can be longitudinal direction, the second direction Y can be a lateral direction, and the third direction Z can be a vertical direction, for example. The heat sink 100 has a length extending along the first direction X, a width extending along the second direction Y, and a height extending along the third direction Z.

As shown in FIG. 1, the heat sink 100 includes, among other things, a base 102, a plurality of fasteners 104 (e.g., spring-loaded captive screws), a plurality of fins 106, and a vapor chamber 108. The base 102 can be positioned relative to a mounting structure and/or Printed Circuit Board (PCB) of an apparatus in which the heat sink 100 is mounted. The fasteners 104 can be used to secure the heat sink 100 to the mounting structure and/or PCB, e.g., so that the vapor chamber 108 is pressed against a Thermal Interface Material (TIM) disposed on an IC, or rather, pressed against the TIM disposed on the device to be cooled.

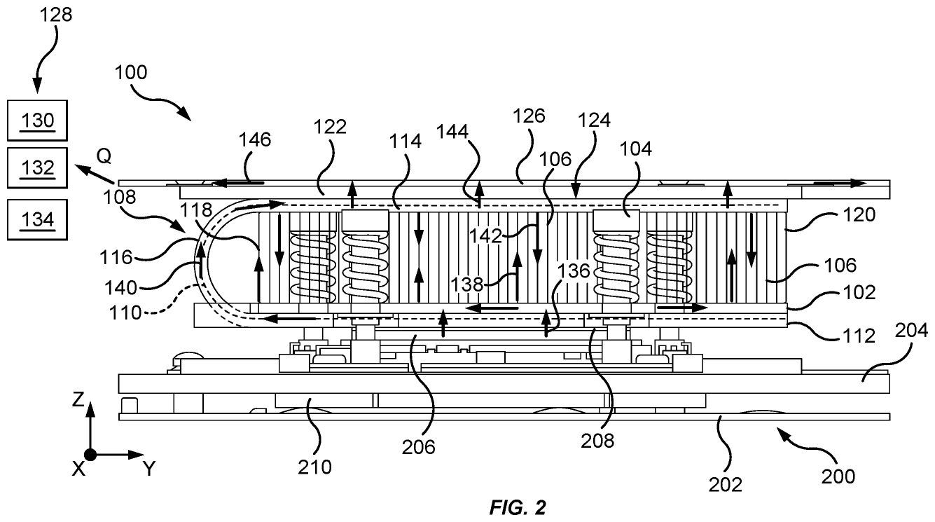

Generally, the vapor chamber 108 defines a chamber 110, which is sealed and filled with a working fluid, such as water. When exposed to heat generated by the IC or device to be cooled, the working fluid vaporizes. The vapor spreads substantially evenly throughout the chamber 110, which absorbs the heat generated by the IC or device to be cooled and transfers the heat to the fins 106 and to additional heat paths. An airflow AF or other fluid can be passed through the heat sink 100 to convectively cool the fins 106 and other components of the heat sink 100. For example, a fan arranged relative to the heat sink 100 can actively provide the airflow AF. The chamber 110 of the vapor chamber 108 is represented by the dashed lines in FIG. 1. As will be explained in detail below, the vapor chamber 108 has a bottom portion and a top portion that is offset from the bottom portion. The bottom portion, which contacts the bottoms of the fins 106 or the base 102 to which the fins 106 are connected, curves up to the top portion, which contacts the tops of the fins 106. The chamber 110 can extend continuously between these portions. The architecture of the heat sink 100 and the vapor chamber 108 thereof will be described in more detail below with reference to FIG. 2.

FIG. 2 is a side view of the heat sink 100 of FIG. 1 incorporated into an apparatus 200. Specifically, in FIG. 2, the heat sink 100 is shown disposed within an apparatus 200 having a chassis or housing 202, a PCB 204, and an IC, which can be a CPU, a Graphics Processing Unit (GPU), a Light Emitting Diode (LED) application, another type of powered device, etc. The IC 206 can be arranged within a socket, for example. An IC TIM layer 208 can be disposed on the IC 206, e.g., on a top surface thereof, and can function to facilitate heat transfer between the IC 206 and the vapor chamber 108. The PCB 204 is seated on a backing plate 210. The housing 202 can include a base wall (shown in FIG. 2), sidewalls, and a top wall collectively defining an enclosure in which the components of the apparatus 200 are disposed. The IC 206 can be coupled with the PCB 204, e.g., to allow for communication between the IC 206 and other components of the apparatus 200. Generally, the heat sink 100 functions to cool the IC 206.

As illustrated in FIG. 2, the vapor chamber 108 includes a bottom portion 112, a top portion 114, and a curved connector 116 that curves up and connects the bottom portion 112 and the top portion 114. The top portion 114 is offset from the bottom portion 112. In the example embodiment of FIG. 2, the top portion 114 is spaced from the bottom portion 112 along the third direction Z, or rather, spaced vertically from the bottom portion 112. Further, in this example, the bottom portion 112 and the top portion 114 are arranged parallel to one another. The bottom portion 112 and the top portion 114 also generally extend in respective planes that are both orthogonal to the third direction Z. Moreover, the bottom portion 112, the top portion 114, and the curved connector 116 can be formed as a single continuous component. In this manner, the vapor chamber 108 can be a unitary monolithic component. In addition, the bottom portion 112, the top portion 114, and the curved connector 116 can collectively form a C-shape as viewed from a side elevation view of the heat sink 100, such as in FIG. 2. Further, in the depicted embodiment of FIGS. 1 and 2, the bottom portion 112 is arranged below the base 102, e.g., along the third direction Z. In this way, the bottom portion 112 can be disposed directly on the IC TIM 208. In other embodiments, however, the bottom portion 112 can be positioned above the base 102, e.g., along the third direction Z. In such embodiments, the base 102 can define an opening to allow the base portion 112 to directly contact the IC TIM 208, for example.

The vapor chamber 108 can extend along at least a portion of the length of the heat sink 100 as depicted in FIG. 1, e.g., along the first direction X, and along at least a portion of the width of the heat sink 100, e.g., along the second direction Y. The bottom portion 112 and the top portion 114 can each extend along the second direction Y at least between a first end fin 118 and a second end fin 120 of the fins 106. In some embodiments, such as in FIG. 1, the curved connector 116 can extend along an entirety of a length of the vapor chamber 108 along the first direction X. In this regard, the bottom portion 112, the top portion 114, and the curved connector 116 can all have a same length dimension along the first direction X.

In addition, the bottom portion 112, the top portion 114, and the curved connector 116 can collectively define the chamber 110 along which a working fluid flows. Accordingly, the chamber 110 can traverse through the bottom portion 112, the curved connector 116, and the top portion 114. The working fluid can be water, for example. In at least some example embodiments, the chamber 110 can be defined as a continuous chamber along which the working fluid flows. The chamber 110 is shown schematically in FIG. 2 by a dashed line extending continuously along the bottom portion 112, the curved connector 116, and the bottom portion 112. It will be appreciated, e.g., by viewing FIG. 1, that the chamber 110 extends along the second direction Y as well. In at least some example embodiments, such as in the embodiment of FIG. 2, the curved connector 116 is curved without any straight sections or portions. A curved connector arranged in this manner can advantageously eliminate or reduce localized pressure drops within a portion of the chamber 110 that extends through the curved connector. In other example embodiments, the curved connector 116 can include at least one straight section or portion, e.g., arranged between two curved sections.

The fins 106 generally extend lengthwise along the first direction X and are spaced from one another along the second direction Y, as shown in FIG. 1. In this manner, the fins 106 generally extend lengthwise parallel with the airflow AF, as illustrated in FIG. 1. As depicted in FIG. 2, the fins 106 can extend between the bottom portion 112 and the top portion 114. In FIG. 2, the fins 106 connect to the top portion 114 at their respective top ends and to the base 102 at their respective bottom ends. The base 102 is arranged in thermal communication with the bottom portion 112 so that heat can be conductively transferred from the bottom portion 112 to the bottom ends of the fins 106 through the base 102. In other example embodiments, the fins 106 can be connected to the top portion 114 at their respective top ends and to the bottom portion 112 at their respective bottom ends. In at least some embodiments, the tops of the fins 106 can be soldered to a bottom surface of the top portion 114 and the bottoms of the fins 106 can be bonded to the bottom portion 112, e.g., directly thereto or bonded to the base 102 that can be soldered to a top surface of the bottom portion 112. Accordingly, the bottom portion 112 and the top portion 114 can be spaced apart by a height of the fins 106 or a height of the fins 106 plus the base of the fins 106. Further, in at least some example embodiments, the vapor chamber 108 and the fins 106 can be arranged so that the curved connector 116 extends out beyond the first end fin 118 of the plurality of fins 106, e.g., along the second direction Y as shown in FIGS. 1 and 2.

As further shown in FIG. 2, the heat sink 100 also includes a TIM layer 122 disposed on the top portion 114. Specifically, the top portion 114 has a planar surface 124 upon which the TIM layer 122 is disposed. As one example, the TIM layer 122 can be TIM2, a thermal pad, graphite over foam, or other thermal interface material. The TIM layer 122 functions to improve the transfer of heat away from the top portion 114. The heat sink 100 also includes a conducting cover 126 that contacts the TIM layer 122. The conducting cover 126 is disposed on the TIM layer 122. In this way, the TIM layer 122 is sandwiched between the top portion 114 and the conducting cover 126. The conducting cover 126 can be formed of a thermally conductive material, such as metal. The TIM layer 122 can transfer heat from the top portion 114 to the conducting cover 126. Accordingly, the conducting cover 126 provides an additional heat transfer path for heat to be transferred away from the top portion 114, or more broadly, the IC 206. The conducting cover 126 can be thermally coupled with one or more additional heat sinks 128, which is represented schematically in FIG. 2.

As one example, the one or more additional heat sinks 128 can include an auxiliary heat sink 130 thermally coupled with the conducting cover 126. For instance, the auxiliary heat sink 130 can include a plurality of fins arranged remotely with respect to the heat sink 100. A heat pipe or thermally conductive connector can transfer heat away from the conducting cover 126 to the auxiliary heat sink 130, for example. As another example, the one or more additional heat sinks 128 can include a housing 132 thermally coupled with the conducting cover 126. For instance, the housing 132 can be the housing 202 of the apparatus 200. A thermally conductive connector can connect the conducting cover 126 with a sidewall, a top wall, and/or a base wall of the housing 202 with the conducting cover 126. In other embodiments, the housing 132 can be a housing other than the housing 202 of the apparatus 200, such as the housing of a component adjacent to the IC 206. As yet another example, the one or more additional heat sinks 128 can include a second cover 134 (e.g., a higher conductivity cover) thermally coupled with the conducting cover 126. The second cover 134 can be directly connected to the conducting cover 126, for example. Other examples are contemplated.

An example manner in which the heat sink 100 can absorb and transfer heat away from a heat source will now be provided with reference to FIGS. 1 and 2. During operation of the apparatus 200, the IC 206 gives off thermal energy or heat. Heat given off by the IC 206 is transferred to the working fluid within the chamber 110 by the IC TIM layer 208, or more specifically, to the working fluid within the portion of the chamber 110 defined by the bottom portion 112. Arrows 136 represent heat being transferred to the working fluid within the portion of the chamber 110 defined by the bottom portion 112. Generally, when heat is applied to the working fluid within the bottom portion 112, e.g., via arrows 136, the working fluid in this vicinity vaporizes and rushes to fill the volume of the chamber 110, which is driven by a pressure difference. When the vaporized working fluid comes into contact with the “condenser section” or a cooler surface, such as in the top portion 114, the curved connector 116, or surfaces of the bottom portion 112 away from the IC TIM layer 208, the vapor condenses and releases heat. The condensed fluid can return to the “evaporator section” of the bottom portion 112, e.g., by way of a wicking structure via capillary action. The evaporator section of the bottom portion 112 generally has the same X-Y area as the IC TIM layer 208.

The working fluid within the bottom portion 112 transfers some of the heat to the base of the fins 106 (e.g., conductively through the base 102 in embodiments in which the fins 106 are connected to the base 102 at their respective bottoms or directly conductively in embodiments in which the fins 106 are directly connected to the bottom portion 112), and this heat moves from bottom-to-top through the fins 106, as represented by upward-facing arrows 138. Moreover, as the vaporized working fluid within the bottom portion 112 rushes to fill the volume of the chamber 110, some heat is transferred to the curved connector 116 and to the top portion 114 of the vapor chamber 108, as represented by arrow 140.

The working fluid within the top portion 114 transfers some heat to the tops of the fins 106, and this heat moves from top-to-bottom through the fins 106, as represented by downward-facing arrows 142. In this regard, heat is transferred to the fins 106 at their respective top ends (from the top portion 114 to the fins 106) and bottom ends (from the bottom portion 112 to the fins 106 or from the base 102 that is in thermal communication with the bottom portion 112). This improves the efficiency of the fins 106 by allowing the tops of the fins 106 to work as efficiently as the bottoms of the fins 106. Moreover, a hotter average temperature and more uniform fin temperature can be achieved, e.g., compared to conventional heat sinks, which consequently results in greater convective heat transfer as the airflow AF passes through the fins 106. The improved fin efficiency is provided, at least in part, by the architecture of the vapor chamber 108, with the bottom portion 112 and the top portion 114 being spaced from one another and connected by the curved connector 116, with the fins 106 being arranged between and connecting the bottom portion 112 and top portion 114.

Further, as shown in FIG. 2, some of the heat given off by IC 206, which is absorbed by the working fluid and carried to the top portion 114, is transferred to the conducting cover 126 by way of the TIM layer 122, as represented by arrows 144. In this regard, the top portion 114 dissipates heat along the first direction X, the second direction Y, and both upward and downward along the third direction Z (upward to the conducting cover 126 via the TIM layer 122 and downward to the tops of the fins 106). Thus, the top portion 114 offers three-dimensional (3D) heat dissipation, with heat being transferred in opposite directions along at least one of the dimensions (e.g., the third direction Z, which can be a vertical direction as noted previously). The bottom portion 112 dissipates heat along the first direction X, the second direction Y, and upward along the third direction Z (e.g., upward to the bottoms of the fins 106). Therefore, the bottom portion 112 also offers 3D heat dissipation. The combination of these cooling capabilities can facilitate efficient cooling of the IC 206.

Furthermore, due at least in part to the architecture of the vapor chamber 108, the bottom portion 112 and top portion 114 can operate substantially isothermally. Stated another way, the bottom portion 112 and top portion 114 can operate substantially at the same temperature during operation, e.g., so that the average temperature of the top portion 114 is at least within a five percent (5%) margin of the average temperature of the bottom portion 112. Accordingly, such an arrangement can provide for the planar surface 124 of the top portion 114 to be an isothermal surface (or nearly isothermal) from which heat can be efficiently removed. This allows the top portion 114 to conduct heat away from the IC 206 using an additional heat path that can provide efficient conduction of heat into the conducting cover 126, and in some embodiments, to the one or more additional heat sinks 128 thermally coupled with the conducting cover 126. Arrow 146 represents heat being transferred along the additional heat path to the one or more additional heat sinks 128, and the arrow Q represents heat being transferred to the one or more additional heat sinks 128. The combined effect of the improved fin efficiency and the additional heat path can produce a compact and highly efficient heat sink, e.g., relative to conventional designs.

In addition to heat transfer advantage of the TIM layer 122, the TIM layer 122 sandwiched between the top portion 114 and the conducting cover 126 can provide support for counteracting shocks and vibrations, which may be particularly advantageous for apparatuses for mobile applications.

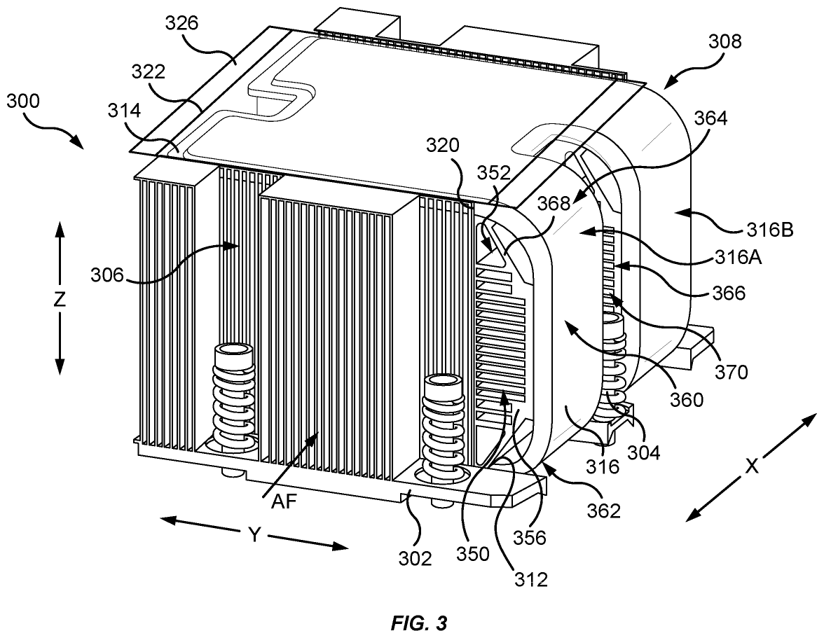

FIG. 3 is a perspective view of a heat sink 300 having a vapor chamber 308 according to another example embodiment of the present disclosure. The heat sink 300 of FIG. 3 is generally configured in a similar manner as the heat sink 100 of FIGS. 1 and 2, and accordingly, the same reference numerals are used to identify like parts, except that three hundred series numerals will be utilized instead of one hundred series numbers as in FIGS. 1 and 2.

For the depicted embodiment of FIG. 3, the heat sink 300 can include a fin array 350 arranged within a volume 352 defined between the curved connector 116 and an end fin (e.g., the second end fin 320) of the fins 306. The fin array 350 can include a backbone 356 and a plurality of fins 358 extending from the backbone 356. The fins 358 can extend from the backbone 356 toward the fins 306, and in some embodiments, the fins 358 can be cantilevered with respect to the backbone 356. In at least some example embodiments, the backbone 356 can be coupled with the base 302 and can contact and be supported by an internal surface of a straight section 360 of the curved connector 316 as shown in FIG. 3. The straight section 360 is arranged between curved sections 362, 364 of the curved connector 116. Further, in at least some embodiments, some of the fins 358 can have different lengths, e.g., along the second direction Y, due to the angled configuration of the backbone 356, e.g., at the top and bottom of the fin array 350. At least one fin 368 of the fins 358 can be angled with respect to the third direction Z, e.g., by forty-five degrees (45°), to fill the portions of the volume 352 proximate the curved sections 362, 364.

As further shown in FIG. 3, in some example embodiments, the curved connector 316 can define a slot 366. The slot 366 can extend from the bottom portion 312 to the top portion 314 in some embodiments. The slot 366 can be defined so as to accommodate one of the fasteners 304 (e.g., one of the spring-loaded captive screws). The slot 366 can essentially separate the curved connector 316 into a first connector 316A and a second connector 316B, both of which extend between and connect the bottom portion 312 and the top portion 314 and both of which define portions of the chamber that extends from the bottom portion 312, through the separate connectors of the curved connector 316, and to the top portion 314. The TIM layer 322 (transparent for illustrative purposes) is shown sandwiched between the top surface of the top portion 314 and the conducting cover 326 (transparent for illustrative purposes). Furthermore, in example embodiment of FIG. 3, a second fin array 370 can arranged within a second volume defined between the end fin (e.g., the second end fin 320) and the second connector 316B. The second fin array 370 can be configured in a same or similar manner as the fin array 350 associated with the first connector 316A.

The same working principle set forth above for the heat sink 100 of FIGS. 1 and 2 is applicable to the heat sink 300 of FIG. 3.

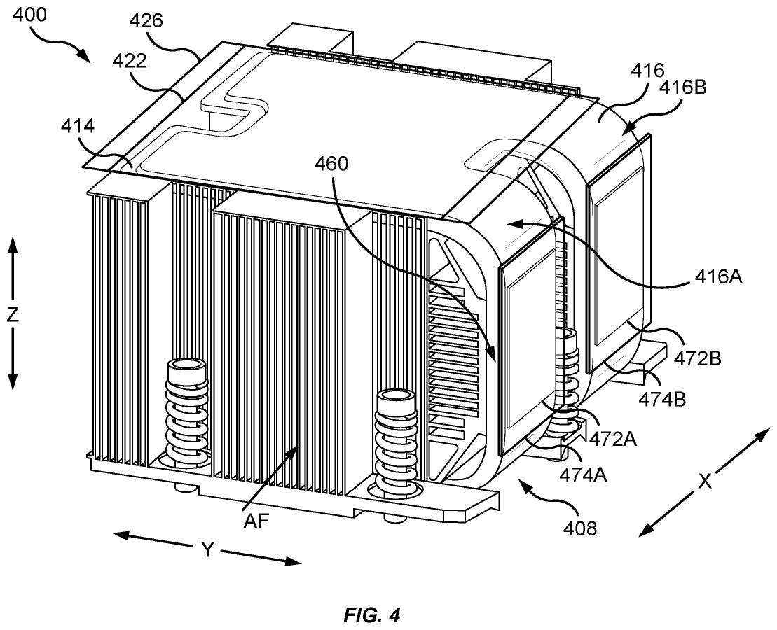

FIG. 4 is a perspective view of a heat sink 400 having a vapor chamber 408 according to another example embodiment of the present disclosure. The heat sink 400 of FIG. 4 is generally configured in a similar manner as the heat sink 300 of FIG. 3, and accordingly, the same reference numerals are used to identify like parts, except that four hundred series numerals will be utilized instead of three hundred series numbers as in FIG. 3.

As shown in FIG. 4, the heat sink 400 includes the TIM layer 422 (transparent for illustrative purposes) sandwiched between the top surface of the top portion 414 and the conducting cover 426 (transparent for illustrative purposes), much like the embodiment of FIG. 3. However, in FIG. 4, a first TIM layer 472A is disposed on the external surface of the first connector 416A, and more particularly, on the external surface of the straight section 460 of the first connector 416A. The external surface of the straight section 460 has a vertically-oriented face and is arranged perpendicular to the second direction Y in this example embodiment. A first conducting cover 474A contacts the first TIM layer 472A. The first TIM layer 472A is sandwiched between the first connector 416A of the curved connected 416 and the first conducting cover 474A.

Similarly, a second TIM layer 472B is disposed on the external surface of the second connector 416B, and more specifically, on the external surface of the straight section of the second connector 416B. The external surface of the straight section has a vertically-oriented face and is arranged perpendicular to the second direction Y in this example embodiment. A second conducting cover 474B contacts the second TIM layer 472B. The second TIM layer 472B is sandwiched between the second connector 416B of the curved connected 416 and the second conducting cover 474B. Moreover, in some alternative embodiments, a single conducting cover can contact both the first and second TIM layers 472A, 472B instead of separate first and second conducting covers 474A, 474B, as shown in FIG. 4.

The first and second conducting covers 474A, 474B can provide further additional heat paths for heat dissipation. The first and second conducting covers 474A, 474B can each be thermally coupled with a same or different additional heat sinks. Particularly, the first and second TIM layers 472A, 472B and their associated first and second conducting covers 474A, 474B function to transfer and dissipate heat from the curved connector 416, e.g., to one or more one or more additional heat sinks thermally coupled thereto, much like the TIM layer 422 and the conducting cover 426 function to transfer heat and dissipate heat from the top portion 414. In some example embodiments, the conducting cover 426 can dissipate heat to a first additional heat sink, e.g., a remote auxiliary heat sink having a plurality of fins, and the first and second conducting covers 474A, 474B can dissipate heat to a second additional heat sink, e.g., to a housing or casing of the apparatus in which the heat sink 400 is arranged. In other example embodiments, the conducting cover 426 and the first and second conducting covers 474A, 474B can dissipate heat to a same additional heat sink.

In some alternative embodiments, a TIM layer, such as a single continuous TIM layer, can be disposed on the top planar surface of the top portion 414 and can extend down the respective first and second connectors 416A, 416B, e.g., terminating at the bottom portion (not labeled in FIG. 4) or at the end of the respective straight sections of the first and second connectors 416A, 416B. Further, a conducting cover, such as a single continuous conducting cover, can extend over the TIM layer such that the TIM layer is sandwiched between the conducting cover and the top portion 414 and at least a portion of the curved connector 416. The conducting cover can be shaped complementary to the external surface of the top portion 414 and the curved connector 416. The conducting cover can dissipate heat to one or more additional heat sinks.

The same working principle set forth above for the heat sink 100 of FIGS. 1 and 2 is applicable to the heat sink 400 of FIG. 4.

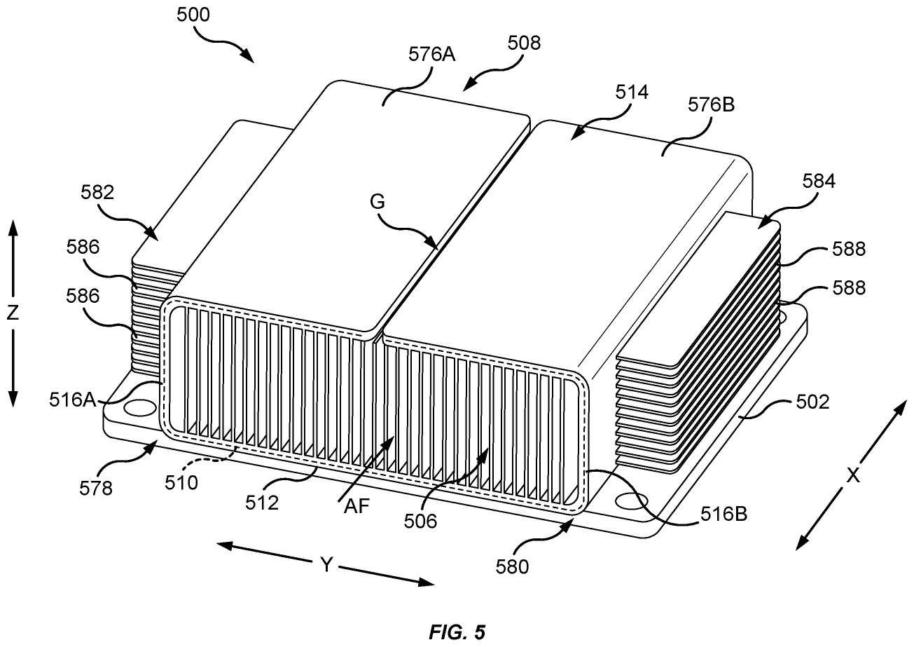

FIG. 5 is a perspective view of a heat sink 500 having a vapor chamber 508 according to another example embodiment of the present disclosure. The heat sink 500 of FIG. 5 is generally configured in a similar manner as the heat sink 100 of FIGS. 1 and 2, and accordingly, the same reference numerals are used to identify like parts, except that five hundred series numerals will be utilized instead of one hundred series numbers as in FIGS. 1 and 2.

As depicted in FIG. 5, the vapor chamber 508 includes a first curved connector 516A and a second curved connector 516B. The first curved connector 516A connects the bottom portion 512 with a first portion 576A of the top portion 514 at a first side 578 of the vapor chamber 508. The second curved connector 516B connects the bottom portion 512 with a second portion 576B of the top portion 514 at a second side 580 of the vapor chamber 508. In this regard, the first and second curved connectors 516A, 516B are spaced from one another along the second direction Y, or rather, a direction that is perpendicular to a direction along which the airflow AF flows through the fins 506. The first and second curved connectors 516A, 516B each have a straight section arranged between two curved sections as illustrated in FIG. 5. In other embodiments, however, the first and second curved connectors 516A, 516B can be curved without any straight sections or portions. The top portion 514 defines a gap G between the first portion 576A of the top portion 514 connected to the first curved connector 516A and the second portion 576B of the top portion 514 connected to the second curved connector 516B. The fins 506 extend between and connect the bottom portion 512 and the first and second portions 576A, 576B of the top portion 514. Accordingly, the bottom portion 512, the first curved connector 516A, the second curved connector 516B, and the top portion 514 can wrap substantially around (e.g., at least ninety percent (90%) around) the plurality of fins 506 as viewed along a side elevation view of the heat sink 500, e.g., as viewed along the first direction X.

The chamber 510 can be defined by the bottom portion 512, the first and second curved connectors 516A, 516B, and the first and second portions 576A, 576B of the top portion 514. The chamber 510 can be a continuous chamber. A cross section of the chamber 510 is represented schematically in FIG. 5 by a dashed line, however, it will be appreciated that the chamber 510 can extend substantially along a length of the vapor chamber 508, e.g., from a forward end to an aft end of the heat sink 500 along the first direction X. Although not shown in FIG. 5, TIM layers can be arranged respectively on the first and second portions 576A, 576B of the top portion 514 and a conducting cover can sandwich the TIM layers between the top planar surface of the top portion 514 and the TIM layers, e.g., to provide an additional heat path. In some embodiments, a single conducting cover can be disposed on the TIM layers. In yet other embodiments, separate conducting covers can be disposed on the respective TIM layers.

In some further example embodiments, the heat sink 500 can include one or more stacked fin arrays arranged relative to the vapor chamber 508. For instance, in FIG. 5, the heat sink 500 includes a first stacked fin array 582 arranged at the first side 578 of the vapor chamber 508 and a second stacked fin array 584 arranged at the second side 580 of the vapor chamber 508. The first stacked fin array 582 includes a plurality of fins 586 stacked in a vertical arrangement. The fins 586 can extend in respective planes that are each perpendicular to the third direction Z. The fins 586 can be soldered to the base 502 or other suitable structure and can contact the external surface of the first curved connector 516A. In this regard, heat from the first curved connector 516A can be transferred to the fins 586 and dissipated. Similarly, the second stacked fin array 584 includes a plurality of fins 588 stacked in a vertical arrangement. The fins 588 can extend in respective planes that are each perpendicular to the third direction Z. The fins 588 can be soldered to the base 502 or other suitable structure and can contact the external surface of the second curved connector 516B. In this regard, heat from the second curved connector 516B can be transferred to the fins 588 and dissipated.

The same working principle set forth above for the heat sink 100 of FIGS. 1 and 2 is applicable to the heat sink 500 of FIG. 5.

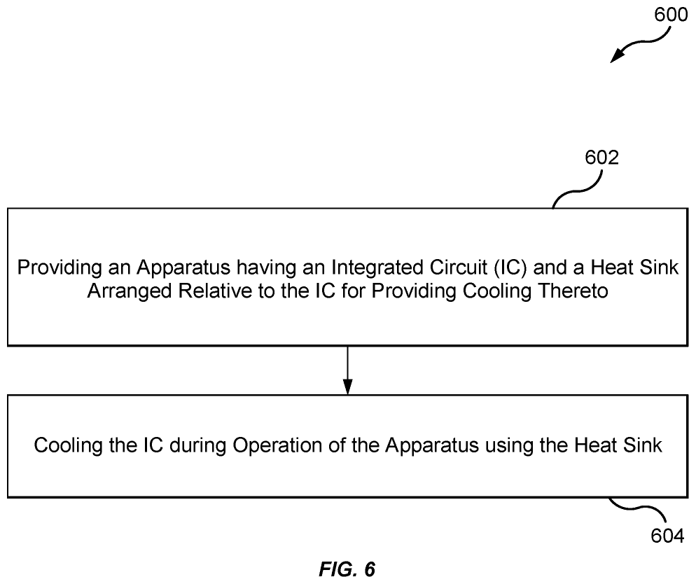

FIG. 6 is a flow diagram for a method 600 of cooling a heat source of an apparatus according to a further example embodiment of the present disclosure. The apparatus can be a network device and the heat source can be an integrated circuit, for example.

At 602, the method 600 includes providing an apparatus having an integrated circuit (IC) and a heat sink arranged relative to the IC for providing cooling thereto. The heat sink includes a vapor chamber having a bottom portion, a top portion spaced from the bottom portion, and a curved connector connecting the bottom portion and the top portion, wherein the bottom portion, the curved connector, and the top portion define a chamber in which a working fluid is received. The heat sink also includes a plurality of fins extending between the bottom portion and the top portion. Further, the heat sink includes a thermal interface material (TIM) layer disposed on at least one surface of the vapor chamber, such as a top planar surface of the top portion or an external surface of the curved connector. The heat sink also includes a conducting cover contacting the TIM layer. In some implementations, the plurality of fins are connected to the top portion at their respective top ends and to the bottom portion at their respective bottom ends. In yet other implementations, the plurality of fins connect to the top portion at their respective top ends and to a base of the heat sink at their respective bottom ends, wherein the base is arranged in thermal communication with the bottom portion (e.g., in a conductive heat transfer relationship, such as being disposed directly adjacent one another in a stacked arrangement). Further, in some implementations, an IC TIM layer can be disposed on the IC, and the bottom portion of the vapor chamber can be directly stacked on the IC TIM layer.

At 604, the method 600 includes cooling the IC during operation of the apparatus using the heat sink. For instance, during operation of the apparatus, the IC can give off thermal energy or heat. Heat given off by the IC can be transferred to the working fluid within the portion of the chamber defined by the bottom portion. When heat is applied to the working fluid within the bottom portion, the working fluid in this vicinity vaporizes and rushes to fill the volume of the chamber. When the vaporized working fluid comes into contact with a cooler surface, such as in the top portion, the vapor condenses and releases heat. The condensed fluid can return to the bottom portion, e.g., by way of a wicking structure via capillary action. This cycle can repeat during operation of the apparatus.

Moreover, the working fluid within the bottom portion transfers some of the heat to the base of the fins, and this heat moves from bottom-to-top through the fins. Moreover, as the vaporized working fluid within the bottom portion rushes to fill the volume of the chamber, some heat is transferred to the curved connector and to the top portion or top portion of the vapor chamber. The working fluid within the top portion transfers some heat to the tops of the fins, and this heat moves from top-to-bottom through the fins. In this way, heat is transferred to the fins at their respective top ends and bottom ends. This improves the efficiency of the fins by allowing the tops of the fins to work as efficiently as the bottoms of the fins and can provide a hotter average temperature and a more uniform fin temperature.

Some of the heat given off by IC, which is absorbed by the working fluid and carried to the curved connector and the top portion, is transferred to the conducting cover by way of the TIM layer. In some implementations, the TIM layer can be disposed on a top planar surface of the top portion. Moreover, in some implementations of the method 600, the bottom portion and top portion can operate substantially isothermally. Stated another way, the bottom portion and top portion can operate substantially at the same temperature during operation, e.g., so that the average temperature of the top portion is at least within a five percent (5%) margin of the average temperature of the bottom portion. Accordingly, the top planar surface of the top portion can be an isothermal surface (or nearly isothermal) with respect to the bottom portion. This allows the top portion to conduct heat away from the IC using an additional heat path that can provide efficient conduction of heat into the conducting cover, and in some implementations, to one or more additional heat sinks thermally coupled with the conducting cover. In some other implementations, additionally or alternatively to the TIM layer disposed on the top planar surface of the top portion, a TIM layer and associated conducting cover can be arranged relative to a surface of the curved connector. Such a TIM layer and conducting cover can provide an additional heat path for heat to be carried away from the IC, such as to an additional heat sink.

To summarize, the combined effect of the improved fin efficiency and the one or more additional heat paths can produce a compact and highly efficient heat sink. Such a heat sink can be used to cool high power devices using air in high density applications, such as cooling an IC of a network apparatus.

In the current disclosure, reference is made to various embodiments. However, the scope of the present disclosure is not limited to specific described embodiments. Instead, any combination of the described features and elements, whether related to different embodiments or not, is contemplated to implement and practice contemplated embodiments. Additionally, when elements of the embodiments are described in the form of “at least one of A and B,” or “at least one of A or B,” it will be understood that embodiments including element A exclusively, including element B exclusively, and including element A and B are each contemplated. Furthermore, although some embodiments disclosed herein may achieve advantages over other possible solutions or over the prior art, whether or not a particular advantage is achieved by a given embodiment is not limiting of the scope of the present disclosure. Thus, the aspects, features, embodiments and advantages disclosed herein are merely illustrative and are not considered elements or limitations of the appended claims except where explicitly recited in a claim(s).

In view of the foregoing, the scope of the present disclosure is determined by the claims that follow.

We claim:

1. A heat sink, comprising:
a vapor chamber, comprising:
a bottom portion;
a top portion spaced from the bottom portion; and
a curved connector connecting the bottom portion and the top portion, wherein the bottom portion, the curved connector, and the top portion define a chamber in which a working fluid is received;
a plurality of fins extending between the bottom portion and the top portion;
a thermal interface material (TIM) layer disposed on the top portion, the curved connector, or both; and
a conducting cover contacting the TIM layer.

2. The heat sink of claim 1, wherein the plurality of fins are connected to the top portion at their respective top ends and to the bottom portion at their respective bottom ends.

3. The heat sink of claim 1, wherein the plurality of fins connect to the top portion at their respective top ends and to a base of the heat sink at their respective bottom ends, wherein the base is arranged in thermal communication with the bottom portion.

4. The heat sink of claim 1, wherein the TIM layer is disposed on a top planar surface of the top portion.

5. The heat sink of claim 1, wherein the TIM layer is disposed on an external surface of the curved connector.

6. The heat sink of claim 1, wherein the bottom portion and the top portion are arranged parallel to one another.

7. The heat sink of claim 1, wherein the bottom portion and the top portion are vertically spaced from one another.

8. The heat sink of claim 1, wherein the bottom portion, the curved connector, and the top portion each have a same length extending along a first direction, and wherein an airflow passes through the plurality of fins along the first direction.

9. The heat sink of claim 1, wherein the bottom portion, the curved connector, and the top portion collectively form a C-shape as viewed along a side elevation view of the heat sink.

10. The heat sink of claim 1, wherein the bottom portion, the curved connector, and the top portion are formed as a single continuous component.

11. The heat sink of claim 1, wherein the bottom portion, the top portion, and the curved connector collectively define the chamber as a continuous chamber.

12. The heat sink of claim 1, wherein the vapor chamber has a first side and a second side, and wherein the curved connector connects the bottom portion and the top portion at the first side, and wherein the vapor chamber has a second curved connector connecting the bottom portion and the top portion at the second side of the vapor chamber.

13. The heat sink of claim 12, wherein the bottom portion, the curved connector, the second curved connector, and the top portion wrap substantially around the plurality of fins as viewed along a side elevation view of the heat sink.

14. The heat sink of claim 12, wherein the top portion defines a gap between a first portion of the top portion connected to the curved connector and a second portion of the top portion connected to the second curved connector.

15. The heat sink of claim 1, further comprising:
a fin array arranged within a volume defined between the curved connector and an end fin of the plurality of fins, the fin array includes a backbone and a plurality of fins extending from the backbone, and wherein the backbone contacts an internal surface the curved connector.

16. The heat sink of claim 1, wherein the curved connector defines a slot that extends from the bottom portion to the top portion and separates the curved connector into a first connector and a second connector both of which extend between and connect the bottom portion and the top portion and both of which define portions of the chamber.

17. The heat sink of claim 1, further comprising:
a stacked fin array arranged having a plurality of fins contacting an external surface of the curved connector.

18. An apparatus, comprising:
an integrated circuit;
a heat sink arranged relative to the integrated circuit for providing cooling thereto, the heat sink comprising:
a vapor chamber having a bottom portion, a top portion spaced from the bottom portion, and a curved connector connecting the bottom portion and the top portion, wherein the bottom portion, the curved connector, and the top portion define a chamber in which a working fluid is received;
a plurality of fins extending between the bottom portion and the top portion;
a thermal interface material (TIM) layer disposed on the top portion, the curved connector, or both; and
a conducting cover contacting the TIM layer.

19. The apparatus of claim 18, further comprising:
an additional heat sink thermally coupled with the conducting cover, and
wherein the additional heat sink is an auxiliary heat sink, a housing, or a second cover.

20. A method, comprising:
providing an apparatus having an integrated circuit (IC) and a heat sink arranged relative to the IC for providing cooling thereto, the heat sink comprises:
a vapor chamber having a bottom portion, a top portion spaced from the bottom portion, and a curved connector connecting the bottom portion and the top portion, wherein the bottom portion, the curved connector, and the top portion define a chamber in which a working fluid is received; a plurality of fins extending between the bottom portion and the top portion; a thermal interface material (TIM) layer disposed on at least one surface of the vapor chamber; and a conducting cover contacting the TIM layer; and
cooling the IC during operation of the apparatus using the heat sink so that:
i) heat is transferred to the plurality of fins at their respective top ends by the top portion and at their respective bottom ends by the bottom portion or a base of the heat sink that is in thermal communication with the bottom portion; and
ii) the bottom portion and the top portion operate substantially isothermally in such a way so as to provide an additional heat path for heat to be transferred from the top portion to the conducting cover by way of the TIM layer and from the conducting cover to one or more additional heat sinks.
